(19) United States
(12) Patent Application Publication
(10) Pub. No.: US 2024/0201244 A1
(43) Pub. Date: Jun. 20, 2024

(54) LIGHT OUTPUT ESTIMATION METHOD FOR LIGHT-EMITTING DEVICE

(71) Applicant: NIKKISO CO., LTD., Tokyo (JP)

(72) Inventors: Kenta URA, Ishikawa (JP); Naoki SHIBATA, Ishikawa (JP)

(73) Assignee: NIKKISO CO., LTD., Tokyo (JP)

(21) Appl. No.: 18/533,998

(22) Filed: Dec. 8, 2023

(30) Foreign Application Priority Data
Dec. 16, 2022 (JP) 2022-201476

(51) Int. Cl. G01R 31/26

(52) U.S. Cl. CPC G01R 31/2635; G01R 31/2642

(57) ABSTRACT

A light output estimation method for light-emitting device is a method for estimating light output of a light-emitting device that has a nitride semiconductor light-emitting element. The light output estimation method for light-emitting device includes a first estimation criterion to estimate light output of the light-emitting device in a period before a predetermined accumulated light emission time T_{X}, and a second estimation criterion to estimate light output of the light-emitting device in a period after the predetermined accumulated light emission time T_{X}. The first estimation criterion and the second estimation criterion are different criteria.

### CROSS-REFERENCE TO RELATED APPLICATIONS

The present application is based on Japanese patent application No. 2022-201476 filed on Dec. 16, 2022, the entire contents of which are incorporated herein by reference.

### TECHNICAL FIELD

The present invention relates to a light output estimation method for light-emitting device.

### BACKGROUND OF THE INVENTION

Patent Literature 1 discloses a method for predicting the lifetime of a photo-semiconductor device. In the method for predicting the lifetime of a photo-semiconductor device described in Patent Literature 1, hourly data of light output of the photo-semiconductor device is collected, a deterioration curve, which is a quadratic function curve, is calculated based on this data, and the light output of the photo-semiconductor device is predicted based on the deterioration curve.

Citation List Patent Literature 1: JP2009-252960A

### SUMMARY OF THE INVENTION

In case of the method for predicting the lifetime of a photo-semiconductor device described in Patent Literature 1, however, there is room for improvement in terms of improving accuracy of output light estimation.

The invention was made in view of such circumstances and it is an object of the invention to provide a light output estimation method for light-emitting device that can improve accuracy of estimating light output of a light-emitting device.

To achieve the object described above, the invention provides a light output estimation method for light-emitting device to estimate light output of a light-emitting device comprising a nitride semiconductor light-emitting element, the method comprising:
a first estimation criterion to estimate light output of the light-emitting device in a period before a predetermined accumulated light emission time T_{X}; and
a second estimation criterion to estimate light output of the light-emitting device in a period after the predetermined accumulated light emission time T_{X},
wherein the first estimation criterion and the second estimation criterion are different criteria.

### Advantageous Effects of the Invention

According to the invention, it is possible to provide a light output estimation method for light-emitting device that can improve accuracy of estimating light output of a light-emitting device.

### BRIEF DESCRIPTION OF DRAWINGS

FIG. 1 is a cross-sectional view showing a first light-emitting device in an embodiment which is mounted on a mounting substrate.

FIG. 2 is a cross-sectional view showing a second light-emitting device in the embodiment which is mounted on the mounting substrate.

FIG. 3 is a graph showing a relationship between accumulated light emission time and light output for a light-emitting device in the embodiment.

FIG. 4 is a flowchart showing a light output estimation method in the embodiment.

### DETAILED DESCRIPTION OF THE INVENTION

### Embodiment

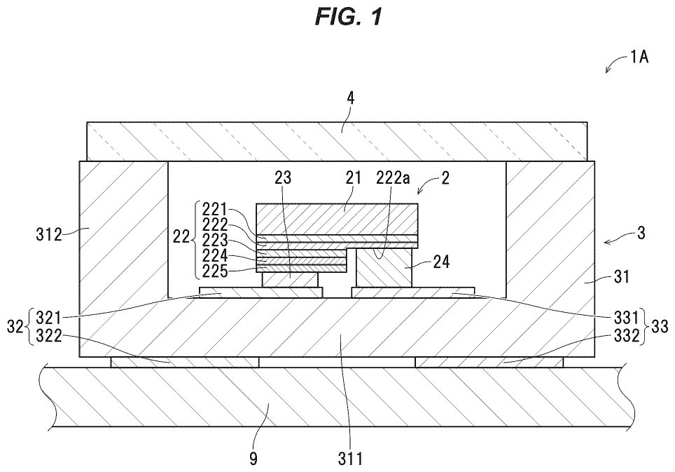

An embodiment of the invention will be described in reference to FIGS. 1 to 4. The embodiment below is described as a preferred illustrative example for implementing the invention. Although some part of the embodiment specifically illustrates various technically preferable matters, the technical scope of the invention is not limited to such specific aspects.

The light output estimation method for light-emitting device in the present embodiment is to estimate light output of a light-emitting device that has a nitride semiconductor light-emitting element. First, an example of a light-emitting device to be subjected to light output estimation by the light output estimation method will be described.

In the present embodiment, two types of light-emitting devices will be described as examples of the light-emitting device which can be subjected to light output estimation by the light output estimation method. These two types of light-emitting devices will be referred to as a first light-emitting device and a second light-emitting device for convenience. In this regard, light-emitting devices which can be subjected to light output estimation are not limited to the two types, the first and second light-emitting devices which will be described below, and other types of light-emitting devices can be subjected to light output estimation as long as a nitride semiconductor light-emitting element is included.

FIG. 1 is a cross-sectional view showing a first light-emitting device 1A which is mounted on a mounting substrate 9. The first light-emitting device 1A is a hermetically-sealed light-emitting device. The first light-emitting device 1A has a nitride semiconductor light-emitting element 2, a package 3, and a window member 4.

The nitride semiconductor light-emitting element 2 constitutes, e.g., a light-emitting diode (LED) or a semiconductor laser (LD: laser diode). In the present embodiment, the nitride semiconductor light-emitting element 2 constitutes a deep ultraviolet LED that emits deep ultraviolet light. The nitride semiconductor light-emitting element 2 has a growth substrate 21, a semiconductor stack structure 22 made of a nitride semiconductor and grown on one side of the growth substrate 21, a p-side element electrode 23, and an n-side element electrode 24.

The growth substrate 21 is a substrate to grow a nitride semiconductor on its principal surface. The growth substrate 21 is a substrate having a property of transmitting light emitted by an active layer 223 (in the present embodiment, deep ultraviolet light), and can be, e.g., a sapphire (Al₂O₃) substrate. Alternatively, e.g., an aluminum nitride (AlN) substrate or an aluminum gallium nitride (AlGaN) substrate, etc., may be used as the growth substrate 21.

In the present embodiment, binary to quaternary group III nitride semiconductors expressed by AlₓGa_{y}In_{1-x-y}N (0≤x≤1, 0≤y≤1, 0≤x+y≤1) can be used for the semiconductor stack structure 22. Al₂Ga_{1-z}N (0≤z≤1)-based semiconductors not containing indium are often used in deep ultraviolet LEDs and are used also in the present embodiment. The semiconductor stack structure 22 is epitaxially grown on the growth substrate 21. A well-known epitaxial growth method such as the Metal Organic Chemical Vapor Deposition (MOCVD) method, the Molecular Beam Epitaxy (MBE) method, or Hydride Vapor Phase Epitaxy (HVPE) method can be used here. The semiconductor stack structure 2 has a buffer layer 221, an n-type semiconductor layer 222, the active layer 223, an electron blocking layer 224 and a p-type semiconductor layer 225 in this order from the growth substrate 21 side.

The buffer layer 221 is made of undoped AlₐGa₁₋ₐN (0≤a≤1). As an example, the buffer layer 221 has an AlN layer made of aluminum nitride (i.e. a=1) and formed on the substrate, and an AlGaN layer made of an undoped aluminum gallium nitride (i.e. 0<a<1) and formed on the AlN layer. However, it is not limited thereto and the buffer layer 221 may be a single layer. When the substrate is an aluminum nitride substrate or an aluminum gallium nitride substrate, the buffer layer 221 may not be necessarily included.

The n-type semiconductor layer 222 is made of Al_{b}Ga_{1-b}N (0≤b≤1) doped with an n-type impurity. The n-type semiconductor layer 222 may have a single-layer structure or may have a multilayer structure.

The active layer 223 is made of Al_{c}Ga_{1-c}N (0≤c≤1) and can have, e.g., a single quantum well structure having one well layer or a multiple quantum well structure having plural well layers. In the active layer 223, electrons supplied from the n-type semiconductor layer 222 recombine with holes supplied from the p-type semiconductor layer 225, resulting in light emission. The active layer 223 emits deep ultraviolet light at a central wavelength of not more than 280 nm.

The electron blocking layer 224 serves to improve efficiency of electron injection into the active layer 223 by suppressing occurrence of the overflow phenomenon in which electrons leak from the active layer 223 to the p-type semiconductor layer 225 (hereinafter, also referred to as the electron blocking effect). The electron blocking layer 224 is made of Al_{d}Ga_{1-d}N (0≤d≤1) with a relatively high Al composition ratio since the higher the Al composition ratio, the wider the bandgap and the easier it is to obtain the electron blocking effect. As an example, the electron blocking layer 224 can be composed of an AlN layer formed on the active layer 223 side and an AlGaN layer with a high Al composition ratio formed on the p-type semiconductor layer 225 side. However, the electron blocking layer 224 is not limited thereto and may be composed of one layer, or not less than three layers. It is also possible to omit the electron blocking layer 224.

The n-type semiconductor layer 225 is made of AlₑGa₁₋ₑN (0≤e≤1) doped with a p-type impurity. The n-type semiconductor layer 225 may have a single-layer structure or may have a multilayer structure.

The p-side element electrode 23 is formed on a surface of the p-type semiconductor layer 225 on the opposite side to the growth substrate 21. Meanwhile, the n-side element electrode 24 is formed on an exposed surface 222a of the n-type semiconductor layer 222 which is exposed from the active layer 223. The p-side element electrode 23 is in ohmic contact with the p-type semiconductor layer 225, and the n-side element electrode 24 is in ohmic contact with the n-type semiconductor layer 222. Each of the p-side element electrode 23 and n-side element electrode 24 can be formed of a single layer of metal film or plural layers of metal film. The nitride semiconductor light-emitting element 2 is arranged so that the p-side element electrode 23 is connected to a p-side package electrode 32 of the package 3 and the n-side element electrode 24 is connected to an n-side package electrode 33 of the package 3.

The package 3 has a box shape which is open on one side. The package 3 has a box-shaped package base 31, the p-side package electrode 32, and the n-side package electrode 33.

The package base 31 is made of an electrically insulating material. The package base 31 has a quadrilateral bottom portion 311 on which the nitride semiconductor light-emitting element 2 is mounted, and a quadrilateral cylindrical side portion 312 erected from a periphery of the bottom portion 311 in a thickness direction of the bottom portion 311. The package base 31 is open at one side of the side portion 312 opposite to the bottom portion 311.

The p-side package electrode 32 and the n-side package electrode 33 are formed on the bottom portion 311. The p-side package electrode 32 has a first p-side package electrode 321 formed on a surface of the bottom portion 311 on the open side of the package base 31 and connected to the p-side element electrode 23, and a second p-side package electrode 322 formed on a surface of the bottom portion 311 opposite to the side where the first p-side package electrode 321 is formed. The first p-side package electrode 321 and the second p-side package electrode 322 are electrically connected to each other through a via (not shown) formed to penetrate the bottom portion 311. The n-side package electrode 33 has a first n-side package electrode 331 formed on the surface of the bottom portion 311 on the open side of the package base 31 and connected to the n-side element electrode 24, and a second n-side package electrode 332 formed on the surface of the bottom portion 311 opposite to the side where the first n-side package electrode 331 is formed. The first n-side package electrode 331 and the second n-side package electrode 332 are electrically connected to each other through a via (not shown) formed to penetrate the bottom portion 311.

The first p-side package electrode 321 and the p-side element electrode 23 are connected through, e.g., a bump (not shown). The second p-side package electrode 322 and the second n-side package electrode 332 are connected to the mounting substrate 9 composed of an external printed circuit board (PCB), etc. The opening of the package base 31 is closed by the window member 4.

The window member 4 is made of a material transmitting light emitted by the nitride semiconductor light-emitting element 2 (in the present embodiment, deep ultraviolet light), and can be made of, e.g., glass, quartz, quartz glass, crystal or sapphire, etc. The ultraviolet light emitted by the nitride semiconductor light-emitting element 2 passes through the window member 4 and is output from the outer surface of the window member 4 to the outside of the first light-emitting device 1A.

The window member 4 and an end surface of the side portion 312 of the package 3 on the open side of the package base 31 are joined over the entire perimeter by AuSn eutectic solder, etc., which seals a space surrounded by the window member 4 and the package 3. In the present embodiment, e.g., nitrogen gas or dry air, etc., is sealed in the space surrounded by the window member 4 and the package 3.

### Second Light-Emitting Device 1B

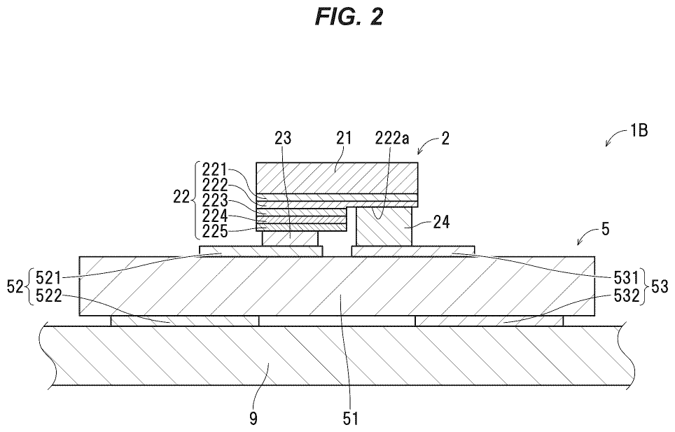

Next, a second light-emitting device 1B, which can be subjected to light output estimation by the light output estimation method in the present embodiment, will be described in reference to FIG. 2. FIG. 2 is a cross-sectional view showing the second light-emitting device 1B which is mounted on the mounting substrate 9. The second light-emitting device 1B is a COS (Chip On Submount) type light-emitting device. The second light-emitting device 1B has the nitride semiconductor light-emitting element 2 and a submount 5. Since the configuration of the nitride semiconductor light-emitting element 2 is the same as the configuration of the nitride semiconductor light-emitting element 2 of the first light-emitting device 1A shown in FIG. 1, the same constituent elements as those of the first light-emitting device 1A are denoted by the same reference signs and the overlapping explanation will be omitted.

The submount 5 has a quadrangular plate-shaped submount base 51, a p-side submount electrode 52, and an n-side submount electrode 53.

The submount base 51 is made of an electrically insulating material. The p-side submount electrode 52 has a first p-side submount electrode 521 formed on one surface of the submount base 51 and connected to the p-side element electrode 23, and a second p-side submount electrode 522 formed on another surface of the submount base 51. The first p-side submount electrode 521 and the second p-side submount electrode 522 are electrically connected to each other through a via (not shown) formed to penetrate the submount base 51. The n-side submount electrode 53 has a first n-side submount electrode 531 formed on the one surface of the submount base 51 and connected to the n-side element electrode 24, and a second n-side submount electrode 532 formed on the other surface of the submount base 51. The first n-side submount electrode 531 and the second n-side submount electrode 532 are electrically connected to each other through a via (not shown) formed to penetrate the submount base 51.

The first p-side submount electrode 521 and the p-side element electrode 23 are connected through, e.g., a bump (not shown). The second p-side submount electrode 522 and the second n-side submount electrode 532 are connected to the external mounting substrate 9. In the second light-emitting device 1B, the nitride semiconductor light-emitting element 2 is not enclosed and is exposed to air, etc. when in use.

### Light Output Estimation Theory for Light-Emitting Device

Next, a light output estimation theory for light-emitting device in the present embodiment will be described.

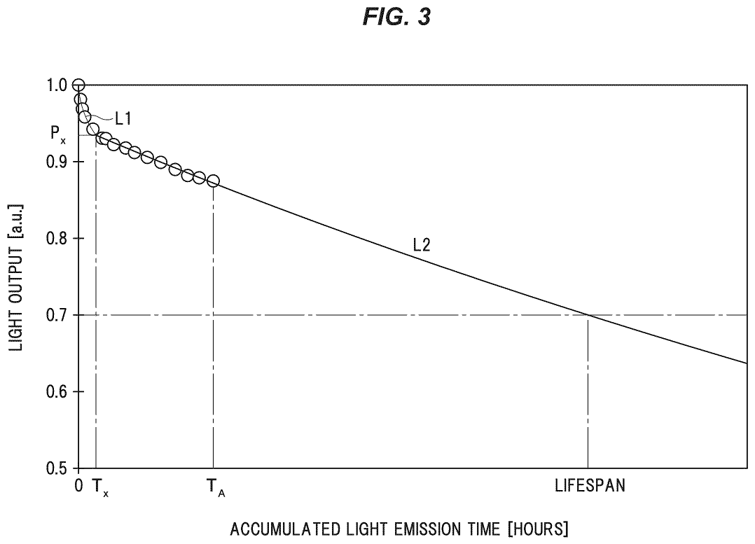

FIG. 3 is a graph showing a relationship between accumulated light emission time and light output for a light-emitting device, where plotted circle symbols indicate measurement points of light output of the light-emitting device. As understood from the results plotted by circles in FIG. 3, a deterioration mode of the light-emitting device having a nitride semiconductor light-emitting element changes around a predetermined accumulated light emission time T_{X}. In the present embodiment, the light-emitting device degrades rapidly (i.e., a decrease in light output over time is rapid) in the early stage until the accumulated light emission time T_{X}, but degradation is relatively slow after the accumulated light emission time T_{X}. Such a change in the deterioration mode around the accumulated light emission time T_{X} is a new finding. Thus, in the present embodiment, to increase accuracy of estimating light output of the light-emitting device, a first estimation criterion for estimation of light output of the light-emitting device in a period before the accumulated light emission time T_{X} is different from a second estimation criterion for estimation of light output of the light-emitting device in a period after the accumulated light emission time T_{X}.

The first estimation criterion is a criterion to estimate light output of the light-emitting device in such a manner that a deterioration rate of the light-emitting device (i.e., the degree of decrease in light output relative to the elapsed time) decreases as light emission time of the light-emitting device increases. The first estimation criterion is expressed as a function including a term proportional to t₁ⁿ¹ (n1 is a value more than 0 and less than 1), where t₁ is any given accumulated light emission time before the accumulated light emission time T_{X}. In the present embodiment, the first estimation criterion follows the following equation (1).

$$\\ \begin{matrix}{P}_{1} ( {t}_{1} ) = {C}_{A} \{ 1 - ( {C}_{B} \times {t}_{1}^{{}_{} Cc} ) \} & ( 1 )\end{matrix}$$

In the equation (1), P₁ is an estimated light output value of the light-emitting device at the any given accumulated light emission time t₁ before the accumulated light emission time T_{X}, and each of C_{A}, C_{B} and C_{C} is a coefficient. The coefficient C_{C} is a coefficient specific to the type of light-emitting device and is n1 mentioned above (i.e., a value more than 0 and less than 1). Here, light-emitting devices of the same type mean, e.g., light-emitting devices having the same product number and manufactured using the same manufacturing method. For example, among hermetically-sealed light-emitting devices as is the first light-emitting device, there are plural types of light-emitting devices (e.g., light-emitting devices with different product numbers). If the type is different, the details of the method for manufacturing the nitride semiconductor light-emitting element, an output wavelength range of the nitride semiconductor light-emitting element and the type of gas sealed in the space surrounded by the package and the window member (i.e., the gas in contact with the nitride semiconductor light-emitting element), etc., may be different even among hermetically-sealed light-emitting devices, and light emission characteristics may vary accordingly. The coefficients C_{A} and C_{B} are coefficients specific to each light-emitting device. By setting the first estimation criterion to follow the equation (1), light output of the light-emitting device at accumulated light emission time before the accumulated light emission time T_{X} can be estimated with high accuracy. In FIG. 3, an example of a curve of the equation (1) is shown by a thin line L1.

Meanwhile, the second estimation criterion is a criterion to estimate light output of the light-emitting device in such a manner that the deterioration rate of the light-emitting device decreases as the light emission time of the light-emitting device increases in a similar manner to the first estimation criterion, but change in the deterioration rate of the light-emitting device over time is more gradual than the first estimation criterion. The second estimation criterion is expressed as a function including a term proportional to exp(−n2×t₂) (n2 is a value more than 0 and less than 0.001), where t₂ is any given accumulated light emission time after the accumulated light emission time T_{X}. In the present embodiment, the second estimation criterion follows the following equation (2).

$$\\ \begin{matrix}{P}_{2} ( {t}_{2} ) = {C}_{D} \times exp ( - {C}_{E} \times {t}_{2} ) & ( 2 )\end{matrix}$$

In the equation (2), t₂ is any given accumulated light emission time after the accumulated light emission time T_{X}, P₂ is an estimated light output value of the light-emitting device at the any given accumulated light emission time t₂, and each of C_{D} and C_{E} is a coefficient. The coefficient C_{E} is a coefficient specific to the type of light-emitting device and is n2 mentioned above (i.e., a value more than 0 and less than 0.001). The coefficient C_{D} is a coefficient specific to each light-emitting device. By setting the second estimation criterion to follow the equation (2), light output of the light-emitting device after the accumulated light emission time T_{X} can be estimated with high accuracy. In FIG. 3, an example of a curve of the equation (2) is shown by a thick line L2.

In the present embodiment, a slope of the equation (1) for the first estimation criterion immediately before the accumulated light emission time T_{X} is greater than a slope of the equation (2) (described later) for the second estimation criterion immediately after the accumulated light emission time T_{X}. That is, after changing from the first estimation criterion to the second estimation criterion, light output of the light-emitting device is estimated in such a manner that the change in the deterioration rate of the light-emitting device over time is more gradual than before changing to the second estimation criterion. For example, the slope of the equation (1) for the first estimation criterion immediately before the accumulated light emission time T_{X} may be the slope of the equation (1) in a period from a predetermined time (e.g., several minutes, several hours, etc.) before the accumulated light emission time T_{X} to the accumulated light emission time T_{X} and the slope of the equation (2) (described later) for the second estimation criterion immediately after the accumulated light emission time T_{X} may be the slope of the equation (2) in a period from the accumulated light emission time T_{X} to a time equal to said predetermined time (e.g., several minutes, several hours, etc.). The predetermined time may be a period between data closest to the accumulated light emission time T_{X} in the measurement data of light output of the light-emitting device and the accumulated light emission time T_{X}.

### Light Output Estimation Method for Light-Emitting Device

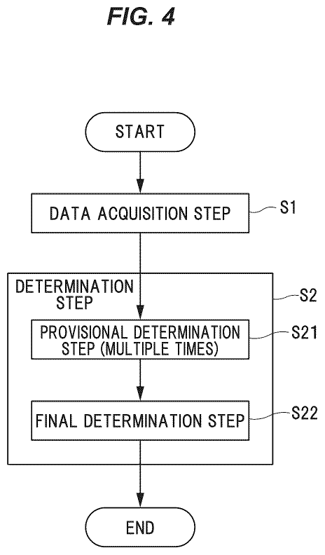

Next, an example of the light output estimation method for light-emitting device in the present embodiment will be described in reference to FIG. 4. FIG. 4 is a flowchart showing the light output estimation method for light-emitting device in the present embodiment.

The light output estimation method for light-emitting device can be used, e.g., when estimating the lifespan of the light-emitting device. As shown in FIG. 3, a light-emitting diode as the light-emitting device is generally defined as having reached the end of its life when the light output drops to 70% of the initial value. The lifespan of light-emitting diodes required in the market is 40,000 hours. 40,000 hours corresponds to approximately four years and six months, and in this regard, it is not realistic to put into production after evaluating each of light-emitting diodes for four years and six months. The light output estimation method for light-emitting device in the present embodiment allows the lifespan of light-emitting diodes to be estimated from light output data collected for a period shorter than the lifespan of the light-emitting diodes (e.g., for a period of several thousand hours, etc.).

The light output estimation method for light-emitting device can be realized by using, e.g., a computer that includes a control unit including a processor and a RAM serving as a calculation area during operation of the processor, and a storage unit having a ROM, hard disk, etc. and storing a program, etc. executed by a CPU.

A data acquisition step S1 of acquiring measurement data of light output of the light-emitting device, and a determination step S2 of determining the accumulated light emission time T_{X} and the various coefficients of equations (1) and (2) are performed in the light output estimation method for light-emitting device in the present embodiment.

The measurement data acquired in the data acquisition step S1 can be measurement data of light output of the light-emitting device up to predetermined accumulated light emission time T_{A} (e.g., not less than 1000 hours, 5000 hours, 10000 hours, 20000 hours, etc.) that is less than the required lifespan of the light-emitting device (e.g., 40000 hours). The measurement data of light output of the light-emitting device acquired in the data acquisition process S1 will be referred to as “measurement data A” for convenience. For example, the data plotted with circles in FIG. 3 can be the measurement data A. The measurement data A can be data of light output of a light-emitting device of the same type as the light-emitting device to be subjected to light output estimation (i.e., data of light output of another light-emitting device which is different from the light-emitting device to be subjected to light output estimation), and is data used to determine the equations (1) and (2).

The measurement data A can be data of light output of the light-emitting device measured at plural predetermined timings up to the accumulated light emission time T_{A}, as shown in FIG. 3. How frequently measuring light output of the light-emitting device can be set to a frequency which allows to understand tendency of deterioration of light output of the light-emitting device. When light output of the light-emitting device is measured more frequently, it is easier to understand the tendency of deterioration of light output of the light-emitting device, but the number of times of measuring the light output may become excessive, requiring more time and effort. Therefore, it is preferable that how frequently measuring light output of the light-emitting device be adjusted to a frequency which allows the tendency of deterioration of light output of the light-emitting device to be fully understood but is not unnecessarily high. Such measurement frequency may be adjusted in various ways according to the deterioration characteristics of each type of light-emitting device. As will be described later, light-emitting devices which include a nitride semiconductor light-emitting element degrade rapidly (i.e., a decrease in light output over time is rapid) in the early stage until the predetermined accumulated light emission time T_{X}, but degradation thereafter is relatively slow. Therefore, e.g., in a period up to the accumulated light emission time T_{X} where the light output changes significantly, light output of the light-emitting device may be measured more frequently than after the accumulated light emission time T_{X}.

The measurement data A acquired in the data acquisition process S1 may also be measurement data of light output measured using one light-emitting device, or may be data that is based on respective measurement data of plural light-emitting devices and is obtained by averaging light output values for each hour, or may be data including respective measurement data of plural light-emitting devices.

The determination step S2 is performed after the data acquisition step S1. The determination step S2 is a step in which the accumulated light emission time T_{X}, the coefficients C_{A} to C_{C} of the equation (1) and the coefficients C_{D} and C_{E} of the equation (2) are determined based on the measurement data A.

The determination step S2 includes a provisional determination step S21 to be performed multiple times, and a final determination step S22. The provisional determination step S21 is a step of provisionally determining the accumulated light emission time T_{X} and the various coefficients of the equations (1) and (2). The final determination step S22 is a step in which a set of the accumulated light emission time T_{X} and the equations (1) and (2), which fit at least a portion of the measurement data A, is selected from plural sets of the accumulated light emission time T_{X} and the equations (1) and (2) that are obtained by performing the provisional determination step S21 multiple times.

In the provisional determination step S21, the coefficients of the function representing the first estimation criterion are determined based on at least a portion of the measurement data A. In particular, first, among the accumulated light emission time T_{X} and the coefficients of the equation (1), the coefficient C_{C} specific to the type of light-emitting device is set to any given value. Then, the undetermined coefficients C_{A} and C_{B} of the equation (1) are determined so that the equation (1) fits at least a portion of data up to accumulated light emission time TB (described later) in the measurement data A. The accumulated light emission time TB is the longest accumulated light emission time in measurement data B of light output of the light-emitting device subjected to light output estimation. Although the details will be described later, the measurement data B is data used for final adjustment of the coefficients C_{A}, C_{B} and C_{D} of the equations (1) and (2) for each individual light-emitting device to be subjected to estimation, and the accumulated light emission time TB can be shorter than the longest accumulated light emission time T_{A} in the measurement data A (can be, e.g., not more than 1000 hours, more specifically, not less than 500 hours and not more than 1000 hours, etc.). The accumulated light emission time TB can be different for each individual light-emitting device, and may be shorter or longer than the accumulated light emission time T_{X}, or may be the same as the accumulated light emission time T_{X}.

Here, the data up to the accumulated light emission time TB in the measurement data A may also include outliers that locally deviate from a general deterioration pattern of the light-emitting device. For example, within several hours after starting the light-emitting device, there may be a light emitting pattern in which light output increases over time, and such measurement data could be an outlier. The fitting described above may be performed so that the first estimation criterion fits data up to the accumulated light emission time TB in the measurement data A excluding outliers. Furthermore, if the measurement data A does not include any outliers, fitting may be performed using all data prior to the accumulated light emission time TB in the measurement data A. FIG. 3 shows the case where there are no outliers in the measurement data A.

A method for the fitting described above is not specifically limited, and it is possible to adopt, e.g., a method in which the equation (1) is determined so that the sum of values, each value corresponding to the difference between the equation (1) and the measurement data A, is small. As an example of such a method, a least squares method may be adopted to determine the equation (1) so that the sum of the squares of values, each value being the difference between the equation (1) and the measurement data A, is minimized.

Next, using the first estimation criterion for which the coefficients have been provisionally determined, an estimated value P_{X} of light output of the light-emitting device at the accumulated light emission time T_{X} (hereinafter, also simply referred to as “the estimated light output value P_{X} at the accumulated light emission time T_{X}”) is calculated.

Next, the coefficients of the function representing the second estimation criterion are provisionally determined based on the estimated light output value P_{X} at the accumulated light emission time T_{X}. In particular, first, among the coefficients of the equation (2), the coefficient C_{E} specific to the type of light-emitting device is set to any given value. Then, the undetermined coefficient C_{D} of the equation (2) is determined to be a value at which the curve of the equation (2) passes through the estimated light output value P_{X} at the accumulated light emission time T_{X}. That is, the estimated light output value P_{X} at the accumulated light emission time T_{X} calculated using the first estimation criterion and the estimated light output value at the accumulated light emission time T_{X} calculated using the second estimation criterion are the same value. In this regard, the method for provisionally determining the equation (2) for the second estimation criterion is not limited thereto, and the equation (2) may be determined so as to fit, e.g., data that includes at least a portion of data after the accumulated light emission time T_{X} in the measurement data A and the estimated light output value P_{X} at the accumulated light emission time T_{X}. In addition, the curve of the equation (2) representing the second estimation criterion may not necessarily pass through the estimated light output value P_{X} at the accumulated light emission time T_{X}.

One set of the accumulated light emission time T_{X} and the equations (1) and (2) is thereby provisionally determined.

Then, the provisional determination step S21 described above is performed multiple times while changing each of the accumulated light emission time T_{X} and the coefficients C_{C} and C_{E} to different values. Plural sets of the accumulated light emission time T_{X} and the equations (1) and (2) are thereby provisionally determined. After completing the multiple times of the provisional determination step S21, the process proceeds to the final determination step S22.

In the final determination step S22, a set of the accumulated light emission time T_{X} and the equations (1) and (2), which fit at least a portion of the measurement data A, is selected from the plural sets of the accumulated light emission time T_{X} and the equations (1) and (2) that are obtained by performing the provisional determination step S21 multiple times. The fitting method which can be adopted is, e.g., a method in which a set of the accumulated light emission time T_{X} and the equations (1) and (2) is determined so that the sum of values, each value corresponding to the difference between the equation (1) to estimate light output of the light-emitting device up to the accumulated light emission time T_{X} or the equation (2) to estimate light output of the light-emitting device after the accumulated light emission time T_{X} and the measurement data A, is small. As an example of such a method, a least squares method may be adopted. The final determination of the accumulated light emission time T_{X} and the equations (1) and (2) is thereby made.

Although the provisional determination step S21 is performed multiple times and the final determination step S22 is then performed in the present embodiment, it is not limited thereto. For example, the accumulated light emission time T_{X} and the equations (1) and (2) obtained by performing the above-described provisional determination step S21 once can be used as-is in the light output estimation method for light-emitting device. However, to increase accuracy of estimating light output of the light-emitting device, it is preferable to perform the provisional determination step S21 multiple times and then perform the final determination step S22.

The final-determined accumulated light emission time T_{X} and equations (1) and (2) can be used as follows.

First, when estimating each hour's light output of the light-emitting device used to obtain the measurement data A, it is possible to estimate light output of the light-emitting device by using the final-determined accumulated light emission time T_{X} and equations (1) and (2) as they are. This makes it possible to predict light output of the light-emitting device outside the range of the existing measurement data A, allowing for estimation of the lifespan, etc., of the light-emitting device.

Next, a case of estimating light output of a light-emitting device which is different from the light-emitting device used to obtain the measurement data A but is of the same type (i.e., a light-emitting device with the same product number; hereafter referred to as the “light-emitting device of the same type”) will be described. In this case, first, among the accumulated light emission time T_{X} and the equations (1) and (2) which are final determined as described above, the coefficients C_{A}, C_{B} and C_{D} (i.e., the coefficients specific to each light-emitting device) are redetermined. In this redetermination, the coefficients C_{A} and C_{B} are determined so that the equation (1) fits the above-described measurement data B which is the light output data of the light-emitting device of the same type, and then, the coefficient C_{D} is determined so that the estimated light output value at the accumulated light emission time T_{X} calculated using the equation (2) matches the estimated light output value at the accumulated light emission time T_{X} calculated using the equation (1). As mentioned above, the final accumulated light emission time TB in the measurement data B can be shorter than the final accumulated light emission time T_{A} in the measurement data A (can be, e.g., not more than 1000 hours, more specifically, not less than 500 hours and not more than 1000 hours, etc.). As mentioned above, when the measurement period for the measurement data B is known in advance, it is preferable that the coefficients of the function for the first estimation criterion be provisionally determined at the stage of the provisional determination step S21 by using only data in the measurement data A for the same period as the measurement period for the measurement data B, from the viewpoint of improving accuracy of estimating light output of light-emitting devices of the same type.

### Functions and Effects of the Embodiment

In the light output estimation method in the present embodiment, the first estimation criterion to estimate light output of the light-emitting device in a period before the predetermined accumulated light emission time T_{X} of the light-emitting device is different from the second estimation criterion to estimate light output of the light-emitting device after the predetermined accumulated light emission time T_{X}. This makes it possible to estimate light output of the light-emitting device with high accuracy even when the light-emitting device includes a nitride semiconductor light-emitting element and its deterioration mode changes around the predetermined accumulated light emission time T_{X}.

The slope of the function for the first estimation criterion immediately before the predetermined accumulated light emission time T_{X} is greater than the slope of the function for the second estimation criterion immediately after the predetermined accumulated light emission time T_{X}. This allows for highly accurate estimation of light output of the light-emitting device which reflects the tendency of light output of the light-emitting device around the predetermined accumulated light emission time T_{X}.

In addition, each of the first estimation criterion and the second estimation criterion is a criterion to estimate light output of the light-emitting device in such a manner that the deterioration rate of the light-emitting device decreases with a lapse of light emission time of the light-emitting device, and the second estimation criterion is a criterion to estimate light output of the light-emitting device in such a manner that change in the deterioration rate of the light-emitting device over time is more gradual as compared to the first estimation criterion. This allows for more accurate estimation of light output of the light-emitting device around the predetermined accumulated light emission time T_{X}.

In addition, the light output estimation method for light-emitting device in the present embodiment includes a step of determining (in the present embodiment, provisionally determining) the coefficients of the function representing the first estimation criterion based on at least a portion of the measurement data A of light output of the light-emitting device, a step of calculating the estimated light output value P_{X} at the accumulated light emission time T_{X} using the first estimation criterion for which the coefficients have been determined, and a step of determining the coefficients of the function for the second estimation criterion based on the estimated light output value P_{X} at the accumulated light emission time T_{X}. Therefore, sudden change in the estimated light output value around the accumulated light emission time T_{X} is suppressed. In the present embodiment, since the estimated light output value P_{X} at the accumulated light emission time T_{X} using the first estimation criterion and the estimated light output value at the accumulated light emission time T_{X} using the second estimation criterion are the same value, sudden change in the estimated value of light output of the light-emitting device around the accumulated light emission time T_{X} is prevented.

In addition, the first estimation criterion includes a term proportional to t₁ⁿ¹ (n1 is a value more than 0 and less than 1), and in particular, follows the above equation (1). The second estimation criterion includes a term proportional to exp(−n2×t₂) (n2 is a value more than 0 and less than 0.001), and in particular, follows the above equation (2). This allows for further accurate estimation of light output of the light-emitting device around the predetermined accumulated light emission time T_{X}.

In addition, the light-emitting device emits deep ultraviolet light. It has been confirmed that the light output estimation method in the present embodiment can achieve highly accurate estimation of light output, especially for light-emitting devices that emit deep ultraviolet light.

As described above, according to the present embodiment, it is possible to provide a light output estimation method for light-emitting device that can improve accuracy of estimating light output of a light-emitting device.

### SUMMARY OF THE EMBODIMENT

Technical ideas understood from the embodiment will be described below citing the reference signs, etc., used for the embodiment. However, each reference sign, etc., described below is not intended to limit the constituent elements in the claims to the members, etc., specifically described in the embodiment.

The first feature of the invention is a light output estimation method for light-emitting device 1A, 1B to estimate light output of a light-emitting device 1A, 1B comprising a nitride semiconductor light-emitting element 2, the method comprising: a first estimation criterion to estimate light output of the light-emitting device 1A, 1B in a period before a predetermined accumulated light emission time T_{X}; and a second estimation criterion to estimate light output of the light-emitting device 1A, 1B in a period after the predetermined accumulated light emission time T_{X}, wherein the first estimation criterion and the second estimation criterion are different criteria. It is thereby possible to improve accuracy of estimating light output of the light-emitting device 1A, 1B.

The second feature of the invention is that, in the first feature, each of the first estimation criterion and the second estimation criterion is expressed as a function of accumulated light emission time of the light-emitting device 1A, 1B, and wherein a slope of the function for the first estimation criterion immediately before the predetermined accumulated light emission time T_{X} is greater than a slope of the function for the second estimation criterion immediately after the predetermined accumulated light emission time T_{X}. This allows for highly accurate estimation of light output of the light-emitting device 1A, 1B which reflects the tendency of light output of the light-emitting device 1A, 1B around the predetermined accumulated light emission time T_{X}.

The third feature of the invention is that, in the first or second feature, each of the first estimation criterion and the second estimation criterion is a criterion to estimate light output of the light-emitting device 1A, 1B in such a manner that a deterioration rate of the light-emitting device 1A, 1B decreases with a lapse of light emission time of the light-emitting device 1A, 1B, and wherein the second estimation criterion is a criterion to estimate light output of the light-emitting device 1A, 1B in such a manner that change in the deterioration rate of the light-emitting device 1A, 1B over time is more gradual as compared to the first estimation criterion.

It is thereby possible to further improve accuracy of estimating light output of the light-emitting device 1A, 1B.

The fourth feature of the invention is that, in any one of the first to third features, each of the first estimation criterion and the second estimation criterion is expressed as a function of accumulated light emission time of the light-emitting device 1A, 1B, and the method comprises: determining a coefficient of the function for the first estimation criterion based on at least a portion of light output data of the light-emitting device 1A, 1B; calculating an estimated light output value P_{X} at the predetermined accumulated light emission time T_{X} by using the first estimation criterion for which the coefficient has been determined; and determining a coefficient of the function for the second estimation criterion based on the estimated light output value P_{X} at the predetermined accumulated light emission time T_{X} calculated using the first estimation criterion for which the coefficient has been determined.

Sudden change in the estimated value around the accumulated light emission time T_{X} is thereby suppressed.

The fifth feature of the invention is that, in the fourth feature, the estimated light output value P_{X} at the predetermined accumulated light emission time T_{X} calculated using the first estimation criterion and an estimated light output value at the predetermined accumulated light emission time T_{X} calculated using the second estimation criterion are the same value.

Sudden change in the estimated light output value of the light-emitting device 1A, 1B around the accumulated light emission time T_{X} is thereby prevented.

The sixth feature of the invention is that, in any one of the first to fifth features, the first estimation criterion is expressed as a function including a term proportional to t₁ⁿ¹ (n1 is a value more than 0 and less than 1), where t₁ is any given accumulated light emission time before the predetermined accumulated light emission time T_{X}.

This allows for further accurate estimation of light output of the light-emitting device 1A, 1B around the predetermined accumulated light emission time T_{X}.

The seventh feature of the invention is that, in the sixth feature, the first estimation criterion is expressed by the following equation (1):

$$\\ \begin{matrix}{P}_{1} ( {t}_{1} ) = {C}_{A} \{ 1 - ( {C}_{B} \times {t}_{1}^{{}_{} Cc} ) \} & ( 1 )\end{matrix}$$

where P₁ is an estimated light output value of the light-emitting device 1A, 1B at the any given accumulated light emission time t₁ and C_{A}, C_{B} and C_{C} are predetermined coefficients.

It is thereby possible to further improve accuracy of estimating light output of the light-emitting device 1A, 1B.

The eighth feature of the invention is that, in any one of the first to seventh features, the second estimation criterion is expressed as a function including a term proportional to exp(−n2×t₂) (n2 is a value more than 0 and less than 0.001), where t₂ is any given accumulated light emission time after the predetermined accumulated light emission time T_{X}.

This allows for further accurate estimation of light output of the light-emitting device 1A, 1B around the predetermined accumulated light emission time T_{X}.

The ninth feature of the invention is that, in the eighth feature, the second estimation criterion is expressed by the following equation (2):

$$\\ \begin{matrix}{P}_{2} ( {t}_{2} ) = {C}_{D} \times exp ( - {C}_{E} \times {t}_{2} ) & ( 2 )\end{matrix}$$

where P₂ is an estimated light output value of the light-emitting device 1A, 1B at the any given accumulated light emission time t₂ and C_{D} and C_{E} are predetermined coefficients. It is thereby possible to further improve accuracy of estimating light output of the light-emitting device 1A, 1B.

The tenth feature of the invention is that, in any one of the first to ninth features, the light-emitting device 1A, 1B emits deep ultraviolet light.

It is thereby possible to improve accuracy of estimating light output of the light-emitting device 1A, 1B.

### ADDITIONAL NOTE

Although the embodiment of the invention has been described, the invention according to claims is not to be limited to the embodiment described above. Further, please note that not all combinations of the features described in the embodiment are necessary to solve the problem of the invention. In addition, the invention can be appropriately modified and implemented without departing from the gist thereof.

1. A light output estimation method for light-emitting device to estimate light output of a light-emitting device comprising a nitride semiconductor light-emitting element, the method comprising:
a first estimation criterion to estimate light output of the light-emitting device in a period before a predetermined accumulated light emission time T_{X}; and
a second estimation criterion to estimate light output of the light-emitting device in a period after the predetermined accumulated light emission time T_{X},
wherein the first estimation criterion and the second estimation criterion are different criteria.

2. The method according to claim 1, wherein each of the first estimation criterion and the second estimation criterion is expressed as a function of accumulated light emission time of the light-emitting device, and wherein a slope of the function for the first estimation criterion immediately before the predetermined accumulated light emission time T_{X} is greater than a slope of the function for the second estimation criterion immediately after the predetermined accumulated light emission time T_{X}.

3. The method according to claim 1, wherein each of the first estimation criterion and the second estimation criterion is a criterion to estimate light output of the light-emitting device in such a manner that a deterioration rate of the light-emitting device decreases with a lapse of light emission time of the light-emitting device, and wherein the second estimation criterion is a criterion to estimate light output of the light-emitting device in such a manner that change in the deterioration rate of the light-emitting device over time is more gradual as compared to the first estimation criterion.

4. The method according to claim 1, wherein each of the first estimation criterion and the second estimation criterion is expressed as a function of accumulated light emission time of the light-emitting device, and wherein the method comprises:
determining a coefficient of the function for the first estimation criterion based on at least a portion of light output data of the light-emitting device;
calculating an estimated light output value P_{X} at the predetermined accumulated light emission time T_{X} by using the first estimation criterion for which the coefficient has been determined; and
determining a coefficient of the function for the second estimation criterion based on the estimated light output value P_{X} at the predetermined accumulated light emission time T_{X} calculated using the first estimation criterion for which the coefficient has been determined.

5. The method according to claim 4, wherein the estimated light output value P_{X} at the predetermined accumulated light emission time T_{X} calculated using the first estimation criterion and an estimated light output value at the predetermined accumulated light emission time T_{X} calculated using the second estimation criterion are the same value.

6. The method according to claim 1, wherein the first estimation criterion is expressed as a function including a term proportional to t₁ⁿ¹ (n1 is a value more than 0 and less than 1), where t₁ is any given accumulated light emission time before the predetermined accumulated light emission time T_{X}.

7. The method according to claim 6, wherein the first estimation criterion is expressed by the following equation (1):
$$\\ \begin{matrix}{P}_{1} ( {t}_{1} ) = {C}_{A} \{ 1 - ( {C}_{B} \times {t}_{1}^{{}_{} Cc} ) \} & ( 1 )\end{matrix}$$
where P₁ is an estimated light output value of the light-emitting device at the any given accumulated light emission time t₁ and C_{A}, C_{B} and C_{C} are predetermined coefficients.

8. The method according to claim 1, wherein the second estimation criterion is expressed as a function including a term proportional to exp(−n2×t₂) (n2 is a value more than 0 and less than 0.001), where t₂ is any given accumulated light emission time after the predetermined accumulated light emission time T_{X}.

9. The method according to claim 8, wherein the second estimation criterion is expressed by the following equation (2):
$$\\ \begin{matrix}{P}_{2} ( {t}_{2} ) = {C}_{D} \times exp ( - {C}_{E} \times {t}_{2} ) & ( 2 )\end{matrix}$$
where P₂ is an estimated light output value of the light-emitting device at the any given accumulated light emission time t₂ and C_{D} and C_{E} are predetermined coefficients.

10. The method according to claim 1, wherein the light-emitting device emits deep ultraviolet light.
